(19) United States
(12) Patent Application Publication
(10) Pub. No.: US 2025/0358971 A1
(43) Pub. Date: Nov. 20, 2025

(54) OPTICAL MODULE

(71) Applicant: InnoLight Technology (Suzhou) Ltd., Suzhou (CN)

(72) Inventors: Jingqi Ji, Suzhou (CN); Zhanwei Wang, Suzhou (CN); XIAN ZHOU, Suzhou (CN)

(21) Appl. No.: 19/286,195

(22) Filed: Jul. 30, 2025

Related U.S. Application Data
(63) Continuation of application No. PCT/CN2023/133962, filed on Nov. 24, 2023.

(30) Foreign Application Priority Data
Feb. 22, 2023 (CN) 202310149751.9

(51) Int. Cl. H05K 7/20

(52) U.S. Cl. CPC H05K 7/2039

(57) ABSTRACT

An optical module includes a housing, an optical interface and an electrical interface being formed at two opposite ends of the housing along a lengthwise direction, respectively; a heat dissipation fin, disposed at the end of the housing close to the optical interface; and a pull ring assembly, comprising a ring arm and a connecting arm connected to each other, the ring arm and the connecting arm being located at different sides of the housing, respectively, and the connecting arm covering a side of the heat dissipation fin facing away from the housing.

### CROSS-REFERENCE TO RELATED PATENT APPLICATION

This application is a continuation application of International Patent Application Ser. No. PCT/CN2023/133962, filed on Nov. 24, 2023, which claims the priority of the China Patent Application No. 202310149751.9, filed on Feb. 22, 2023. The entirety of each of the above patent applications is hereby incorporated by reference herein and made a part of this specification.

### FIELD OF THE DISCLOSURE

The present disclosure relates to a technical field of an optical communication equipment, and more particularly to an optical module.

### BACKGROUND OF THE DISCLOSURE

An optical module is an optoelectronic device that performs an optical-to-electrical conversion and an electrical-to-optical conversion. In recent years, as a market scale of global cloud computing data centers continuously expands and construction of 5th generation mobile networks is fully under way, market requirements of the optical module having high speed is increased on a daily basis. Various series and types of products have been launched one after the other, providing the best optical module solutions for customers of cloud computing data centers, wireless access, and transmission, etc.

Since the optical module generates a lot of heat during operation, if the heat is not dissipated in time, a stability of the optical module will be affected. Accordingly, the optical module usually has a heat dissipation fin disposed thereon to dissipate the heat of the optical module. Moreover, the optical module is usually detachably plugged into an optical cage through a pull ring. However, the pull ring occupies a part of a space of a housing of the optical module, thereby resulting in a shortened length of the heat dissipation fins, and causing a heat dissipation effect and a heat dissipation efficiency of the current optical module to be poor.

### SUMMARY OF THE DISCLOSURE

The present disclosure provides an optical module for improving a heat dissipation effect and a heat dissipation efficiency of the optical module.

The present disclosure provides an optical module including a housing that has two opposite ends along a lengthwise direction respectively forming an optical interface and an electrical interface, a heat dissipation fin disposed on one end of the housing adjacent to the optical interface, and a pull ring assembly including a ring arm and a connecting arm that are connected to each other. The ring arm and the connecting arm are respectively arranged at different sides of the housing, and the ring arm covers one side of the heat dissipation fin facing away from the housing.

In one embodiment of the present disclosure, the pull ring assembly is movably connected to the housing. When the pull ring assembly is assembled on the housing and is not subject to an external force, the connecting arm covers one side of the heat dissipation fin facing away from the housing.

In one embodiment of the present disclosure, a quantity of the heat dissipation fin is at least two, each of the heat dissipation fins is formed on one surface of the housing and extends along the lengthwise direction of the housing, the heat dissipation fins are spaced apart on one surface of the housing in a direction perpendicular to the lengthwise direction of the housing, and the heat dissipation fins adjacent to each other defines a heat dissipation channel therebetween. The connecting arm covers one side of the heat dissipation channel facing away from the housing.

In one embodiment of the present disclosure, the heat dissipation fin includes a first fin portion and a second fin portion connected to the first fin portion. The second fin portion is arranged at one end of the first fin portion away from the optical interface, and the connecting arm covers one side of the first fin portion away from the housing.

In one embodiment of the present disclosure, a first heat dissipation channel is formed between the first fin portions of the heat dissipation fins adjacent to each other, a second heat dissipation channel is formed between the second fin portions of the heat dissipation fins adjacent to each other, and the first heat dissipation channel and the second heat dissipation channel are in spatial communication with each other.

In one embodiment of the present disclosure, the first fin portion has a first surface facing away from the housing, the second fin portion has a second surface facing away from the housing, and the first surface is closer to the housing than the second surface.

In one embodiment of the present disclosure, the optical module further includes a cover plate covering one side of the second fin portion facing away from the housing.

In one embodiment of the present disclosure, an orthographic projection of each of the heat dissipation channels on the housing is all within an orthographic projection of the connecting arm on the housing.

In one embodiment of the present disclosure, the optical module further includes an elastic component embedded in the heat dissipation channel, wherein the elastic component is connected to the connecting arm. The pull ring assembly is movably disposed on the housing, and the elastic component is configured to drive the pull ring assembly to reset after the pull ring assembly is pulled.

In one embodiment of the present disclosure, the heat dissipation channel has a first step surface formed therein, and the pull ring assembly further includes a limiting portion connected to the connecting arm. The limiting portion is embedded in the heat dissipation channel. The elastic component is embedded in the heat dissipation channel, the elastic component is clamped between the first step surface and the limiting portion, and the elastic component drives the pull ring assembly to reset through the limiting portion.

In one embodiment of the present disclosure, the optical module further includes an elastic component disposed on a side surface of the housing, and the elastic component is connected to the ring arm. The pull ring assembly is movably connected to the housing, and the elastic component is configured to drive the pull ring assembly to reset after the pull ring assembly is pulled.

In one embodiment of the present disclosure, the pull ring assembly further includes a pull ring connected to the connecting arm. An end portion of the connecting arm connected to the pull ring is spaced apart from the housing to define a ventilation opening between the end portion and the housing or disposed on a position of the connecting arm adjacent to the pull ring, and the ventilation opening and the heat dissipation channel are in spatial communication with each other.

The beneficial effects of the present disclosure are that, the present disclosure provides the optical module different from the prior art. The optical module includes the housing and the heat dissipation fin disposed on the housing, and the optical module dissipates heat through the heat dissipation fin. Moreover, the optical module further includes the pull ring assembly, the connecting arm of the pull ring assembly covers one side of the heat dissipation fin facing away from the housing. In other words, the heat dissipation fin provided by the present disclosure extends to one side of the connecting arm facing toward the housing, that is, the space between the connecting arm and the housing is configured to set the heat dissipation fin. When the connecting arm provided by the present disclosure occupies a partial space of the housing, it is beneficial to design the heat dissipation fins to have enough length to ensure the heat dissipation effect and heat dissipation efficiency of the optical module. Accordingly, the present disclosure can improve the heat dissipation effect of the optical module and the heat dissipation efficiency of the optical module compared with the prior art.

### BRIEF DESCRIPTION OF THE DRAWINGS

In order to more clearly illustrate technical solutions in the embodiments of the present disclosure, the drawings required for use in a description of embodiments will be briefly described as follows. Obviously, the following description of the drawings are only some embodiments of the present disclosure. Those skilled in the art may further obtain other drawings according to these drawings without creative work.

FIG. 1 is a schematic view of a structure of an optical module according to a first embodiment of the present disclosure;

FIG. 2 is a schematic exploded view of the structure of the optical module of FIG. 1;

FIG. 3 is a schematic view of the structure of the optical module of FIG. 1 without the pull ring assembly;

FIG. 4 is a schematic view of a section A of the structure of the optical module of FIG. 3;

FIG. 5 is a top schematic view of the structure of the optical module of FIG. 1;

FIG. 6 is a cross-sectional schematic view taken along line B-B of the structure of the optical module of FIG. 5;

FIG. 7 is a schematic view of a section C of the structure of the optical module of FIG. 6;

FIG. 8 is a schematic view of a structure of an optical module according to a second embodiment of the present disclosure;

FIG. 9 is a cross-sectional schematic view of a structure of an optical module according to a third embodiment of the present disclosure;

FIG. 10 is a schematic view of a section D of the structure of the optical module of FIG. 9; and

FIG. 11 is a schematic view of a structure of an optical module according to a fourth embodiment of the present disclosure.

### DETAILED DESCRIPTION OF THE EXEMPLARY EMBODIMENTS

The following description combines drawings of embodiments provided by the present disclosure to clearly and completely describe technical solutions of the embodiments provided by the present disclosure. Obviously, the embodiments described in specification are only one part of the embodiments of the present disclosure, rather than all embodiments. Based on the embodiments of the present disclosure, other embodiments obtained by those skilled in the art without creative work are all within a scope of protection of the present disclosure. In addition, it should be understood that the specific implementations described herein are only configured to illustrate and explain the present disclosure and are not configured to limit the present disclosure. In the present disclosure, in the absence of any statement to the contrary, directional words used, for example, “up”, “down”, “left”, and “right”, generally refer to the up, down, left, and right of the device as actually used or in the working state, and specifically the drawing direction in the drawings.

In the present disclosure, unless the context clearly dictates and limits otherwise, the terms “connected”, “coupled”, “stacked”, etc., should be understood in a broad sense, for example, it can be fixedly connected, detachably connected, or integrally connected; it can be directly connected, or indirectly connected through an intermediate medium, and it can be inner portions of two components that are in spatial communication with each other or the interaction relationship of the two components. For those skilled in the art, specific meanings of the aforementioned terms of the present disclosure can be understood according to specific situations.

The present disclosure provides an optical module, which is described in detail below. It should be noted that a description order of the following embodiments is not provided as a limitation of a preferred order of the embodiments of the present disclosure. In the following embodiments, the description of each of the embodiments has its own emphasis, and the parts that are not detailed in any of embodiments can refer to the related descriptions of other embodiments.

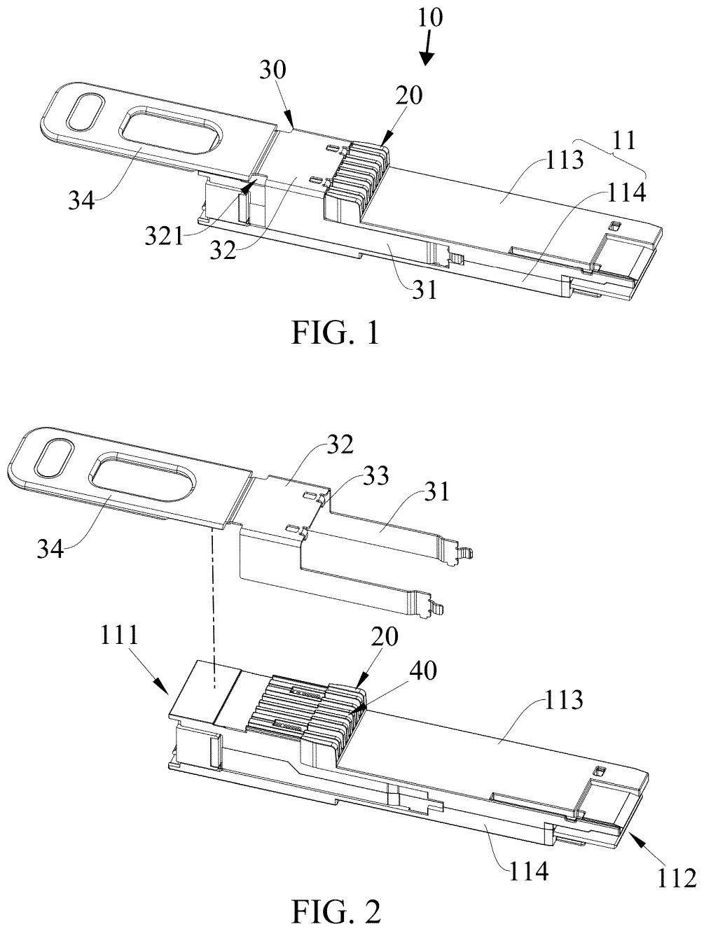

Referring to FIG. 1 and FIG. 2, FIG. 1 is a schematic view of a structure of an optical module according to a first embodiment of the present disclosure, and FIG. 2 is a schematic exploded view of the structure of the optical module of FIG. 1.

In one embodiment, an optical module 10 includes a housing 11. The housing 11 is a basic carrier of the optical module 10 and is configured to carry and protect other components of the optical module 10. For example, the housing 11 can be configured to carry a circuit board, an optoelectronic chip, an optical lens, an optical interface (e.g., an interface component 17 described below), and other components, etc., and is not limited thereto. Two opposite ends of the housing 11 along a lengthwise direction respectively forms an optical interface 111 and an electrical interface 112, an external optical fiber is optically connected to the optical module 10 through the optical interface 111, and the optical module 10 is electrically connected to an external device through the electrical interface 112.

The optical module 10 further includes a heat dissipation fin 20, the heat dissipation fin 20 is disposed on one end of the housing 11 adjacent to the optical interface 111. Considering that the optical module 10 generates a lot of heat during operation and needs to dissipate heat in time, the housing 11 has the heat dissipation fin 20 disposed thereon. During the operation of the optical module 10, a heat dissipation airflow passes through the optical module 10 to exchange heat with the optical module 10 and dissipate heat from the optical module 10. The heat dissipation fins 20 disposed on the housing 11 can expand a heat exchange area of the optical module 10, thereby improving a heat dissipation effect of the optical module 10 and enhancing a heat dissipation efficiency of the optical module 10.

The optical module 10 further includes a pull ring assembly 30. The pull ring assembly 30 is disposed on the housing 11. The optical module 10 is detachably plugged into an optical cage through the pull ring assembly 30. Specifically, the pull ring assembly 30 includes a ring arm 31, a connecting arm 32, and a pull ring 34. The ring arm 31 and the pull ring 34 are respectively connected to the connecting arm 32. The ring arm 31 and the connecting arm 32 are respectively arranged at different sides of the housing 11. The pull ring assembly 30 is movably disposed on the housing 11. The user unlocks the pull ring assembly 30 from the optical cage by pulling the pull ring assembly 30, so as to pull the optical module 10 out from the optical cage. Specifically, the user pulls the pull ring 34 to enable the pull ring assembly 30 as a whole to move relative to the housing 11, and the optical module 10 is unlocked from the optical cage through the ring arm 31, thereby allowing the optical module 10 to be pulled out from the optical cage.

FIG. 2 exemplarily shows that the pull ring assembly 30 includes two ring arms 31, the two ring arms 31 are connected to each other through the connecting arm 32, and the two ring arms 31 are disposed on two opposite sides of the housing 11.

It should be noted that the housing 11 includes an upper housing 113 and a lower housing 114. The upper housing 113 and the lower housing 114 are stacked with each other and connected to each other to define a space for carrying the aforementioned circuit board, optoelectronic chip, optical lens, optical interface and other components, etc. When the optical module 10 is plugged into the optical cage, the upper housing 113 is arranged above the lower housing 114. The pull ring 34 is arranged at one side of the upper housing 113 facing away from the lower housing 114, or the pull ring 34 is arranged at one side of the lower housing 114 facing away from the upper housing 113. FIG. 1 and FIG. 2 exemplarily show that the connecting arm 32 of the pull ring assembly 30 and the heat dissipation fin 20 are arranged at a surface of the upper housing 113 facing away from the lower housing 114. The connecting arm 32 occupies a partial space of the aforementioned surface.

In the present embodiment, the connecting arm 32 of the pull ring assembly 30 covers one side of the heat dissipation fin 20 facing away from the housing 11. In other words, the heat dissipation fin 20 extends to one side of the connecting arm 32 facing toward the housing 11, that is, a space between the connecting arm 32 and the housing 11 is configured to set the heat dissipation fin 20. In the present embodiment, when the connecting arm 32 occupies a partial space of the housing 11, it is beneficial to design the heat dissipation fins 20 to have enough length to ensure the heat dissipation effect and the heat dissipation efficiency of the optical module 10. Accordingly, the present embodiment can improve the heat dissipation effect of the optical module 10 and enhance the heat dissipation efficiency of the optical module 10 compared with the prior art.

Moreover, when the pull ring assembly 30 is assembled on the housing 11 and is not subject to an external force, the connecting arm 32 covers one side of the heat dissipation fin 20 facing away from the housing 11. When the optical module 10 is needed to be pulled out from the optical cage, the user pulls the pull ring assembly 30 to unlock the optical module 10 from the optical cage to allow the optical module 10 to be pulled out from the optical cage.

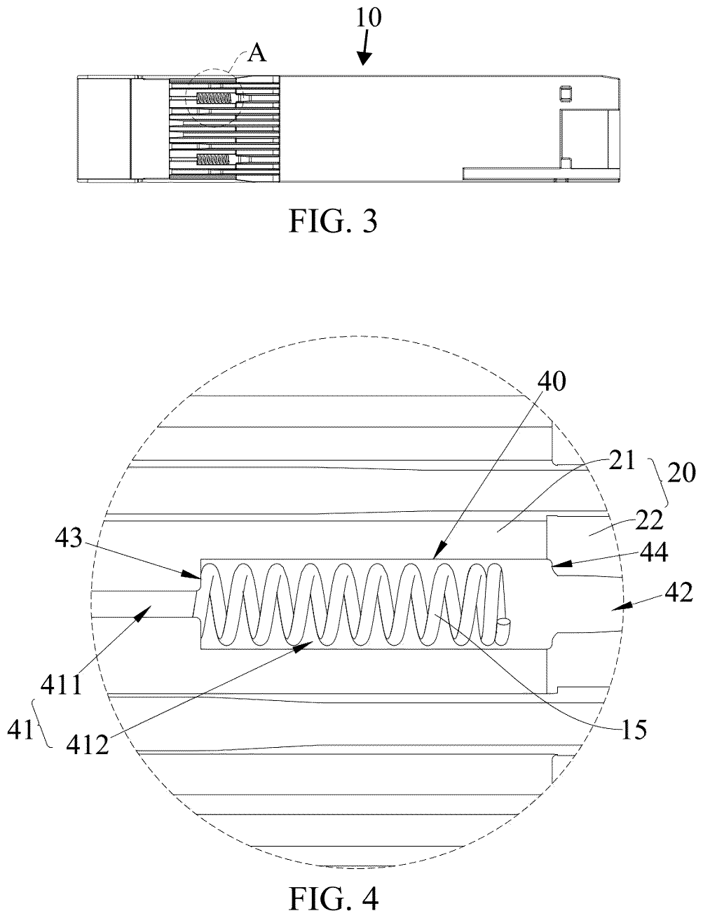

As shown in FIG. 3 and FIG. 4, FIG. 3 is a schematic view of the structure of the optical module of FIG. 1 without the pull ring assembly, and FIG. 4 is a schematic view of a section A of the structure of the optical module of FIG. 3.

In one embodiment, a quantity of the heat dissipation fin 20 is at least two. Each of the heat dissipation fins 20 is formed on one surface of the housing 11 and extends along the lengthwise direction of the housing 11, the heat dissipation fins 20 are spaced apart from each other on one surface of the housing 11 in a direction that is perpendicular to the lengthwise direction of the housing 11, and the heat dissipation fins 20 adjacent to each other define a heat dissipation channel 40 therebetween. A direction of the heat dissipation fins 20 that are spaced apart from each other is parallel to a surface of the housing 11 having the heat dissipation fins 20 arranged thereon (e.g., as shown in FIG. 1, the surface of the upper housing 113 facing away from the lower housing 114).

Based on the above, compared with a situation that one side of the heat dissipation channel 40 facing away from the housing 11 is not covered, the connecting arm 32 of the pull ring assembly 30 of the present embodiment is provided as a channel cover plate to cover the heat dissipation channel 40, which means that the heat dissipation channel 40 can be formed as a relatively closed channel structure in a circumferential direction thereof. Accordingly, the heat dissipation airflow has a higher flow rate by passing through the heat dissipation channel 40, thereby improving the heat dissipation effect of the optical module 10 and enhancing the heat dissipation efficiency of the optical module 10.

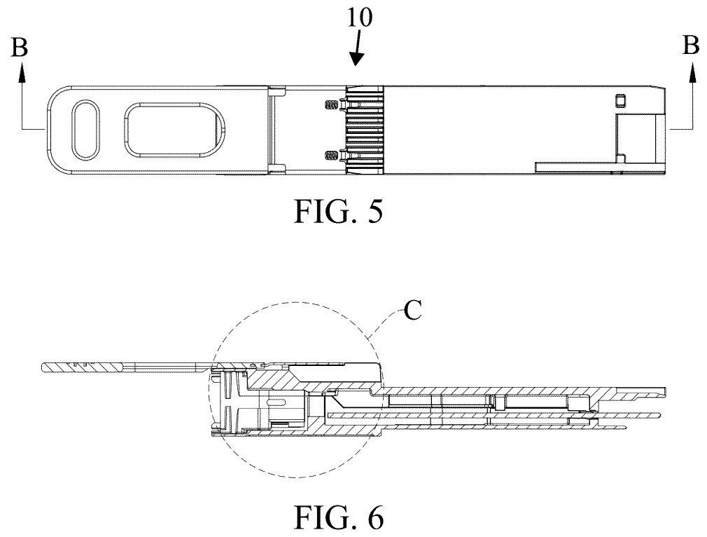

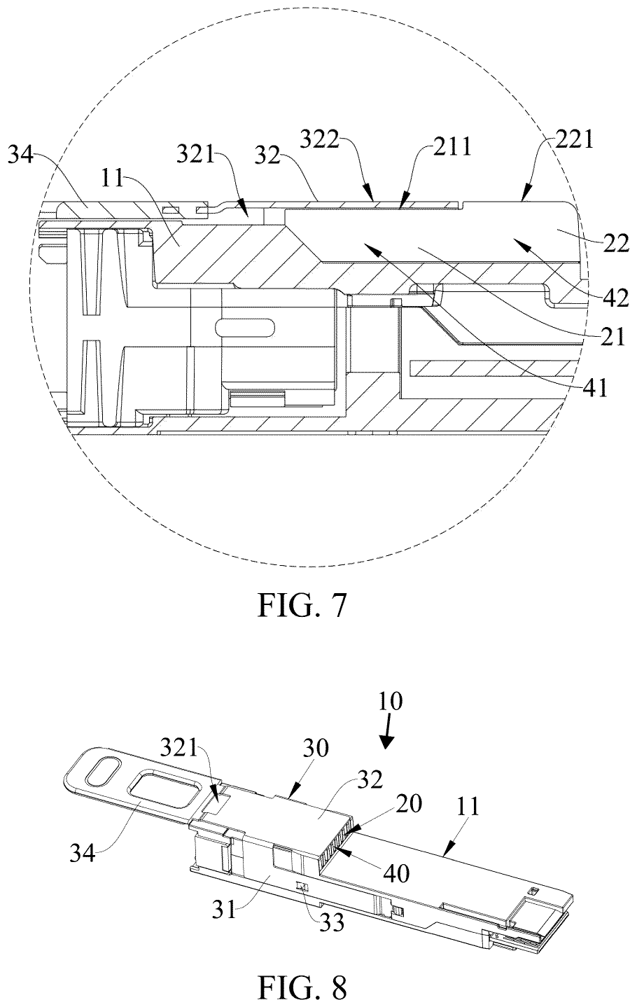

Specifically, referring to FIG. 5 to FIG. 7, an end portion of the connecting arm 32 connected to the pull ring 34 is spaced apart from the housing 11 to define a ventilation opening 321 between the end portion and the housing (as shown in FIG. 1 and FIG. 7) or disposed on a position of the connecting arm 32 adjacent to the pull ring 34 (as shown in FIG. 8). The ventilation opening 321 and the heat dissipation channel 40 are in spatial communication with each other. The heat dissipation airflow is discharged from the ventilation opening 321 after passing through the heat dissipation channel 40, or the heat dissipation airflow enters the heat dissipation channel 40 from the ventilation opening 321, thereby achieving the heat dissipation of the optical module 10.

Referring to FIG. 7, in one embodiment, the heat dissipation fin 20 includes a first fin portion 21 and a second fin portion 22. The first fin portion 21 is connected to the second fin portion 22, and the second fin portion 22 is arranged at one end of the first fin portion 21 away from the optical interface 111. The heat dissipation channel 40 includes a first heat dissipation channel 41 and a second heat dissipation channel 42. The first heat dissipation channel 41 is formed between the first fin portions 21 of the heat dissipation fins 20 adjacent to each other, the second heat dissipation channel 42 is formed between the second fin portions 22 of the heat dissipation fins 20 adjacent to each other, and the first heat dissipation channel 41 and the second heat dissipation channel 42 are in spatial communication with each other.

In the present embodiment, the connecting arm 32 covers one side of the first fin portion 21 facing away from the housing 11, that is, the connecting arm 32 covers one side of the first heat dissipation channel 41 facing away from the housing 11. In other words, in the present embodiment, the heat dissipation fin 20 extends from an external portion to a space between the connecting arm 32 and the housing 11, one part of the heat dissipation fin 20 (i.e., the first fin portion 21) is arranged between the connecting arm 32 and the housing 11, and the remaining part of the heat dissipation fin 20 (i.e., the second fin portion 22) is arranged at an external portion of the connecting arm 32. In the present embodiment, the heat dissipation fin 20 has a greater length, so that a heat exchange area of the heat dissipation fin 20 can be expanded, the heat dissipation effect of the optical module 10 can be improved, and the heat dissipation efficiency of the optical module 10 can be enhanced.

Specifically, the first fin portion 21 has a first surface 211 facing away from the housing 11, the second fin portion 22 has a second surface 221 facing away from the housing 11. The first surface 211 is closer to the housing than the second surface 221, and the connecting arm 32 covers the first surface 211.

Based on the above, in the present embodiment, the first surface 211 of the first fin portion 21 and the second surface 221 of the second fin portion 22 have a height difference therebetween. Specifically, the first surface 211 is lower than the second surface 221. After the connecting arm 32 covers the first surface 211, a height of the connecting arm 32 can be decreased, so as to reduce a risk of a height of the optical module 10 exceeding a height requirement due to the connecting arm 32 covering the heat dissipation fin 20.

Moreover, the connecting arm 32 has a third surface 322 facing away from the housing 11. In the present embodiment, the third surface 322 is closer to the housing 11 than the second surface 221, that is, the third surface 322 is lower than the second surface 221 to extremely reduce the risk of the height of the optical module 10 exceeding the height requirement. Alternatively, in the present embodiment, the third surface 322 is flush with the second surface 221, which can not only prevent the height of the optical module 10 from exceeding the height requirement, but also prevent a height of the first fin portion 21 from being too low, so as to ensure that the first fin portion 21 can provide enough heat exchange area to ensure the heat dissipation effect and the heat dissipation efficiency of the optical module 10.

It should be noted that, in an example of the connecting arm 32 covering the first fin portion 21, a height of a partial position of the first fin portion 21 is lower than a height of the second fin portion 22. On the one hand, the first fin portion 21 can extend to one side of the connecting arm 32 facing the housing 11 by decreasing the height of the first fin portion 21, that is, the connecting arm 32 covers the first fin portion 21. On the other hand, a position of the housing 11 having the first fin portion 21 arranged thereon needs to avoid the components disposed in an internal portion of the housing 11 (e.g., the interface component 17, etc., described below). Accordingly, the height of the partial position of the first fin portion 21 needs to be disposed at a lower height to prevent the position of the housing 11 having the first fin portion 21 arranged thereon from penetrating. In the present embodiment, the height of the second fin portion 22 is higher, which is beneficial for ensuring that the heat dissipation fins 20 can provide enough heat exchange area, thereby ensuring the heat dissipation effect and the heat dissipation efficiency of the optical module 10.

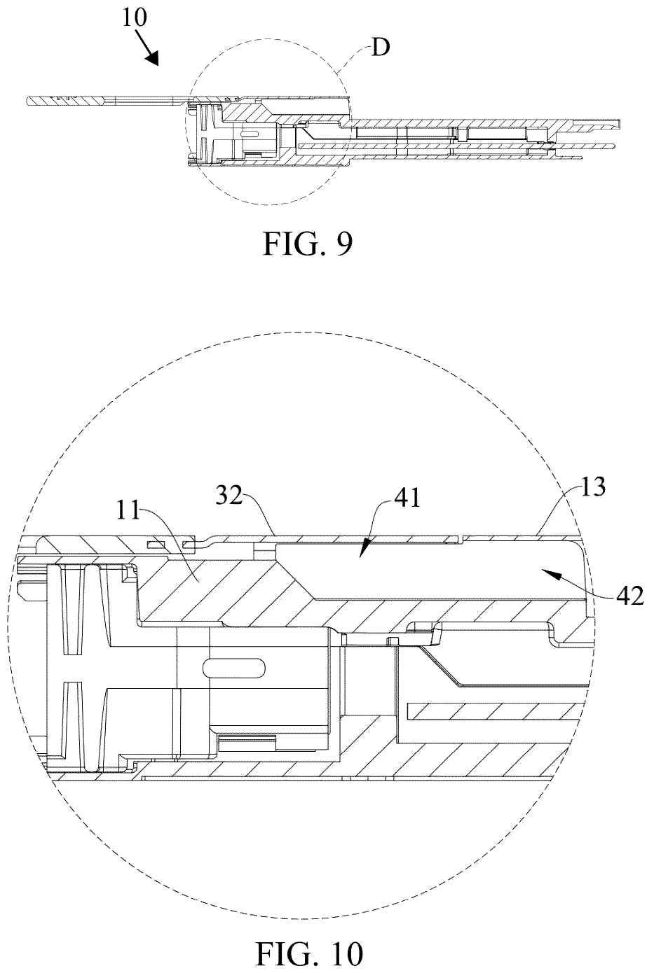

Referring to FIG. 9 and FIG. 10, FIG. 9 is a cross-sectional schematic view of a structure of an optical module according to a third embodiment of the present disclosure, and FIG. 10 is a schematic view of a section D of the structure of the optical module of FIG. 9.

In one embodiment, in a situation that the aforementioned connecting arm 32 covers one side of the first fin portion 41 facing away from the housing 11, the optical module 10 of the present embodiment further includes a cover plate 13. The cover plate 13 covers one side of the second fin portion 22 facing away from the housing 11, that is, the cover plate 13 covers one side of the second heat dissipation channel 42 facing away from the housing 11.

Based on the above, in the present embodiment, the cover plate 13 is provided as a channel cover plate to cover on the second heat dissipation channel 42, so that the second heat dissipation channel 42 can be formed as a relatively closed channel structure in a circumferential direction thereof. Accordingly, the heat dissipation airflow has a higher flow rate by passing through the second heat dissipation channel 42, thereby improving the heat dissipation effect of the optical module 10 and enhancing the heat dissipation efficiency of the optical module 10.

Optionally, the pull ring assembly 30 and the cover plate 13 can be made of sheet metal components, etc., to facilitate processing and shaping of the pull ring assembly 30 and the cover plate 13, so that the pull ring assembly 30 and the cover plate 13 can adapt to structures of the housing 11 and can be greatly engaged with the housing 11.

Naturally, in other embodiments provided by the present disclosure, the optical module 10 can be not provided with the cover plate 13, one side of the second heat dissipation channel 42 facing away from the housing 11 is not covered, and is not limited herein.

Referring to FIG. 8, in one embodiment, an orthographic projection of each of the heat dissipation channels 40 on the housing 11 is all within an orthographic projection of the connecting arm 32 on the housing 11. In other words, in the present embodiment, the connecting arm 32 fully covers the heat dissipation fin 20 and the heat dissipation channel 40 between the heat dissipation fins 20 adjacent to each other, and the connecting arm 32 is provided as the channel cover plate fully covers the heat dissipation channel 40, so that the heat dissipation channel 40 as a whole can be formed as the relatively closed channel structure in the circumferential direction thereof. Accordingly, the heat dissipation airflow can have a higher flow rate by passing through the heat dissipation channel 40, thereby improving the heat dissipation effect of the optical module 10 and enhancing the heat dissipation efficiency of the optical module 10.

Referring to FIG. 4, in one embodiment, the optical module 10 further includes an elastic component 15. The elastic component 15 is embedded in the heat dissipation channel 40, and the elastic component 15 is connected to the connecting arm 32 of the pull ring assembly 30. The pull ring assembly 30 is movably disposed on the housing 11, and the optical module 10 can be pulled out from the optical cage by pulling the pull ring assembly 30, and the elastic component 15 is configured to drive the pull ring assembly 30 to reset after the pull ring assembly 30 is pulled.

Specifically, when the optical module 10 is plugged into the optical cage and the user needs to pull the optical module 10 out from the optical cage, the user pulls the pull ring assembly 30 by pulling the pull ring 34 to move the pull ring assembly 30 from a first position to a second position, so that the optical module 10 is unlocked from the optical cage to allow the user to pull the optical module 30 out from the optical cage. At this time, the pull ring assembly 30 drives the elastic component 15 to be elastically deformed. After the user pulls out the optical module 10, the user removes a pulling force, and the elastic component 15 drives the pull ring assembly 30 to reset in response to its elastic recovery force, so that the pull ring assembly 30 is reset from the second position to the first position.

Naturally, in other embodiments provided by the present disclosure, the elastic component 15 can be disposed out of the heat dissipation channel 40, or the elastic component 15 can be disposed on a side surface of the housing 11, that is, the elastic component 15 is connected to the ring arm 31 of the pull ring assembly 30. At this time, the elastic component 15 can also drive the pull ring assembly 30 to reset after the pull ring assembly 30 is pulled. The following description describes an example of the elastic component 15 that is embedded in the heat dissipation channel 40, which is only for purpose of discussion and is not intended to be limiting.

Optionally, the elastic component 15 can be a spring, or a component having an ability of elastic deformation, etc. An inner portion of the elastic component 15 is hollow, the heat dissipation airflow in the heat dissipation channel 40 where the elastic component 15 is located can smoothly pass through the elastic component 15 through an outer circumference and/or the inner portion of the elastic component 15. In other words, the present embodiment uses the heat dissipation channel 40 to set the elastic component 15, which is beneficial to simplify the structure of the optical module 10, and the elastic component 15 can still ensure that the heat dissipation airflow can normally pass through the heat dissipation channel 40 where the elastic component 15 is located, thereby ensuring the heat dissipation effect and heat dissipation efficiency of the optical module 10.

In one embodiment, the heat dissipation channel 40 has a first step surface 43 formed therein. The first heat dissipation channel 41 includes a first subchannel segment 411 and a second subchannel segment 412. The first subchannel segment 411 and the second subchannel segment 412 are in spatial communication with each other. The first subchannel segment 411 is arranged away from the second heat dissipation channel 42 relative to the second subchannel segment 412. The first step surface 43 is formed by a connecting junction of the first subchannel segment 411 and the second subchannel segment 412, and the first step surface 43 faces toward the second heat dissipation channel as shown in FIG. 4.

The pull ring assembly 30 further includes a limiting portion 33 as shown in FIG. 2. The limiting portion 33 is connected to the connecting arm 32, and the limiting portion 33 is embedded in the heat dissipation channel 40 and is specifically embedded in the second subchannel segment 412. The elastic component 15 is embedded in the heat dissipation channel 40 and is specifically embedded in the second subchannel segment 412, the elastic component 15 is clamped between the first step surface 43 and the limiting portion 33, and the elastic component 15 drives the pull ring assembly 30 to reset through the limiting portion 33.

Furthermore, a second step surface 44 is formed by a connecting junction of the second heat dissipation channel 42 and the second subchannel segment 412, the second step surface 44 faces toward the first subchannel segment 411, and the second subchannel segment 412 is configured to limit a further movement of the limiting portion 33 during a process of resetting the pull ring assembly 30 as shown in FIG. 4.

For example, the heat dissipation fins 20 of the housing 11 forms a plurality of heat dissipation channels 40. The optical module 10 includes two elastic components 15, the two elastic components 15 are respectively arranged in different heat dissipation channels 40. The limiting portions 33 correspond to the elastic components 15 one by one, and each of the elastic components 15 abuts against a corresponding one of the limiting portions 33. One part of the heat dissipation channels 40 has the elastic component 15 disposed therein, and the remaining part of the heat dissipation channels 40 does not have the elastic component 15 disposed therein. The limiting portion 33 is arranged at one side of the connecting arm 32 away from the pull ring 34, the limiting portion 33 is bent toward the housing 11 relative to the connecting arm 32 to embed into the heat dissipation channel 40, so that the elastic component 15 can abut against the limiting portion 33. The first step surface 43 and the second step surface 44 are arranged in sequence along an extending direction of the heat dissipation channel 40, one end of the elastic component 15 facing toward the pull ring 34 abuts against the first step surface 43, and one end of the elastic component 15 facing away from the pull ring 34 abuts against the limiting portion 33.

FIG. 8 exemplarily shows a situation of the limiting portion 33 disposed on a side surface of the housing 11. It can be understood that the elastic component 15 corresponding to the limiting portion 33 is also disposed on the side surface of the housing 11. The elastic component 15 is connected to the ring arm 31, the elastic component 15 is specifically connected to the ring arm 31 through the limiting portion 33, and the elastic component 15 drives the pull ring assembly 30 to reset after the pull ring assembly 30 is pulled.

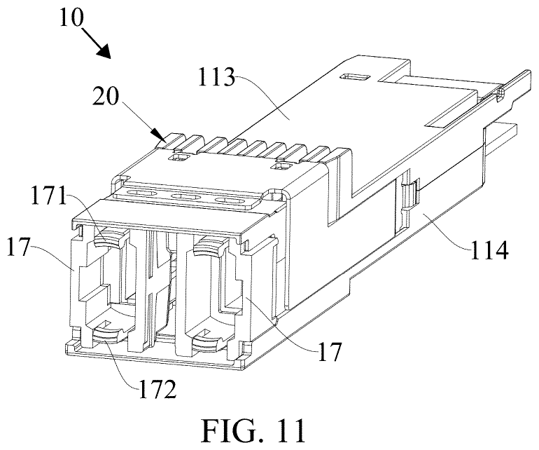

Referring to FIG. 11, FIG. 11 is a schematic view of a structure of an optical module according to a fourth embodiment of the present disclosure.

In one embodiment, the optical module 10 further includes the interface component 17. The interface component 17 is arranged in a space formed by the upper housing 113 and the lower housing 114 that are connected to each other. The interface component 17 has a first jaw 171 and a second jaw 172 that are spaced apart from each other, the first jaw 171 and the second jaw 172 respectively cooperate with a locking structure of a jumper wire interface, so as to lock the jumper wire interface in the interface component 17.

In the present embodiment, a relative direction of the first jaw 171 and the second jaw 172 is parallel to a relative direction of the upper housing 113 and the lower housing 114, that is, the interface component 17 is vertically placed in the optical module 10. In order to adapt the interface component 17 to be vertically placed, the optical module 10 is designed with enough height space, which is beneficial for designing the heat dissipation fins 20 on the housing 11, so that the heat dissipation fins 20 can provide enough heat exchange area to ensure the heat dissipation effect and heat dissipation efficiency of the optical module 10.

Optionally, the interface component 17 can specifically be an MPO (Multi-fiber Push On) adapter, etc. Moreover, FIG. 11 exemplarily shows that the optical module 10 specifically includes two interface components 17, and the two interface components 17 are arranged side by side.

In conclusion, the present disclosure provides the optical module. The optical module includes the housing and the heat dissipation fin disposed on the housing, and the optical module dissipates heat through the heat dissipation fin. Moreover, the optical module further includes the pull ring assembly, the connecting arm of the pull ring assembly covers one side of the heat dissipation fin facing away from the housing. In other words, the heat dissipation fin provided by the present disclosure extends to one side of the connecting arm facing toward the housing, that is, the space between the connecting arm and the housing is configured to set the heat dissipation fin. When the connecting arm provided by the present disclosure occupies a partial space of the housing, it is beneficial to design the heat dissipation fins to have enough length to ensure the heat dissipation effect and heat dissipation efficiency of the optical module. Accordingly, the present disclosure can improve the heat dissipation effect of the optical module and the heat dissipation efficiency of the optical module compared with the prior art.

The optical module provided by the present disclosure is introduced in detail above. This article uses specific examples to illustrate the principles and the implementations of the present disclosure. The foregoing description of the embodiments is only configured to help understand the method and the core idea of the present disclosure. At the same time, for those skilled in the art, according to the concept of the present disclosure, the specific implementations and the application scopes may be changed. In conclusion, the content of this specification should not be understood as a limitation of the present disclosure.

What is claimed is:

1. An optical module, comprising:
a housing, wherein two opposite ends of the housing along a lengthwise direction respectively form an optical interface and an electrical interface;
a heat dissipation fin disposed on one end of the housing adjacent to the optical interface; and
a pull ring assembly including a ring arm and a connecting arm that are connected to each other, the ring arm and the connecting arm are respectively arranged at different sides of the housing, and the connecting arm covers one side of the heat dissipation fin facing away from the housing.

2. The optical module according to claim 1, wherein the pull ring assembly is movably connected to the housing, and wherein, when the pull ring assembly is assembled on the housing and is not subject to an external force, the connecting arm covers one side of the heat dissipation fin facing away from the housing.

3. The optical module according to claim 1, wherein a quantity of the heat dissipation fin is at least two, each of the heat dissipation fins is formed on one surface of the housing and extends along the lengthwise direction of the housing, the heat dissipation fins are spaced apart from each other on one surface of the housing in a direction perpendicular to the lengthwise direction of the housing, and the heat dissipation fins adjacent to each other define a heat dissipation channel therebetween;
wherein the connecting arm covers one side of the heat dissipation channel facing away from the housing.

4. The optical module according to claim 3, wherein the heat dissipation fin includes:
a first fin portion; and
a second fin portion connected to the first fin portion, wherein the second fin portion is arranged at one end of the first fin portion away from the optical interface, and the connecting arm covers one side of the first fin portion away from the housing.

5. The optical module according to claim 4, wherein a first heat dissipation channel is formed between the first fin portions of the heat dissipation fins adjacent to each other, a second heat dissipation channel is formed between the second fin portions of the heat dissipation fins adjacent to each other, and the first heat dissipation channel and the second heat dissipation channel are in spatial communication with each other.

6. The optical module according to claim 4, wherein the first fin portion has a first surface facing away from the housing, the second fin portion has a second surface facing away from the housing, and the first surface is closer to the housing than the second surface.

7. The optical module according to claim 4, further comprising:
a cover plate covering one side of the second fin portion facing away from the housing.

8. The optical module according to claim 3, wherein an orthographic projection of each of the heat dissipation channels on the housing is all within an orthographic projection of the connecting arm on the housing.

9. The optical module according to claim 3, further comprising:
an elastic component embedded in the heat dissipation channel, wherein the elastic component is connected to the connecting arm;
wherein the pull ring assembly is movably disposed on the housing, and the elastic component is configured to drive the pull ring assembly to reset after the pull ring assembly is pulled.

10. The optical module according to claim 9, wherein the heat dissipation channel has a first step surface formed therein, and the pull ring assembly further includes:
a limiting portion connected to the connecting arm, wherein the limiting portion is embedded in the heat dissipation channel;
wherein the elastic component is embedded in the heat dissipation channel, the elastic component is clamped between the first step surface and the limiting portion, and the elastic component drives the pull ring assembly to reset through the limiting portion.

11. The optical module according to claim 1, further comprising:
an elastic component disposed on a side surface of the housing, wherein the elastic component is connected to the ring arm;
wherein the pull ring assembly is movably connected to the housing, and the elastic component is configured to drive the pull ring assembly to reset after the pull ring assembly is pulled.

12. The optical module according to claim 3, wherein the pull ring assembly further includes:
a pull ring connected to the connecting arm;
wherein an end portion of the connecting arm connected to the pull ring is spaced apart from the housing to define a ventilation opening between the end portion and the housing or disposed on a position of the connecting arm adjacent to the pull ring, and the ventilation opening and the heat dissipation channel are in spatial communication with each other.
